(19) United States
(12) Patent Application Publication
(10) Pub. No.: US 2023/0143137 A1
(43) Pub. Date: May 11, 2023

(54) ELECTRONIC COMPONENT, ELECTRONIC DEVICE, AND METHOD FOR MANUFACTURING ELECTRONIC COMPONENT

(71) Applicant: KYOCERA Corporation, Kyoto-shi, Kyoto (JP)

(72) Inventor: Akira OIKAWA, Higashiomi-shi (JP)

(73) Assignee: KYOCERA Corporation, Kyoto-shi, Kyoto (JP)

(21) Appl. No.: 17/918,796

(22) PCT Filed: Apr. 21, 2021
(86) PCT No.: PCT/JP2021/016134

§ 371 Date: Oct. 13, 2022

(30) Foreign Application Priority Data
Apr. 21, 2020 (JP) 2020-075245

(51) Int. Cl. H03H 9/25; H03H 3/08; H03H 9/145; H03H 9/64; H03H 9/10

(52) U.S. Cl. CPC H03H 9/25; H03H 3/08; H03H 9/145; H03H 9/64; H03H 9/1064

(57) ABSTRACT

In an electronic component, a chip includes a vibrating functional part and a terminal on a first surface thereof. An intermediate member is stacked on the first surface. The intermediate member includes a first through hole above the functional part and surrounds the functional part in plan view. A lid is stacked on a surface of the intermediate member on the opposite side from the chip and closes the first through hole. A bonding member includes an upper end located on the opposite side of the lid from the intermediate member. The intermediate member surrounds the terminal as well as the functional part. The lid includes a second through hole overlapping the terminal out of the functional part and the terminal. The bonding member includes a center portion located inside the second through hole and a lower end located inside the first through hole and bonded to the terminal.

### TECHNICAL FIELD

The present disclosure relates to wafer-level package-type electronic components, electronic devices including such electronic components, and methods of manufacturing electronic components.

### BACKGROUND OF INVENTION

An electronic component is known that includes a functional part on a main surface of a chip (Typically the widest surface. For example, a plate-shaped front or back surface. The same applies hereinafter.) (For example, refer to Patent Literatures 1 and 2). In Patent Literatures 1 and 2, a chip includes a piezoelectric substrate and an excitation electrode located on a main surface of the piezoelectric substrate. The region of the chip where the excitation electrode is disposed constitutes a functional part. When a voltage (from another perspective, an electrical signal) is applied to the main surface of the piezoelectric substrate using the excitation electrode, acoustic waves (for example, surface acoustic waves (SAWs)) that propagate along the main surface of the piezoelectric substrate are excited. Conversely, acoustic waves are also converted into an electrical signal. The functional part that performs such conversion between electrical signals and acoustic waves is used, for example, as a resonator or filter.

In Patent Literatures 1 and 2, the electronic component is configured as a so-called wafer-level package-type chip. Specifically, the electronic component includes a frame stacked on the main surface of the chip and surrounding the excitation electrode when the main surface of the chip is viewed in plan view, and a lid stacked on the frame so as to close the opening (through hole) of the frame. As a result, the upper surface of the chip is sealed in a state where a space surrounded by the chip, the frame, and the lid is formed above the excitation electrode. The space contributes to facilitating propagation of acoustic waves (in other words, vibration of a vibration region).

The lid is provided with bumps (bonding members) composed of solder to allow the electronic component to be surface mounted on a circuit board, for example. The bumps are electrically connected to the excitation electrode. Specifically, wiring connected to the excitation electrode and pads connected to the wiring are provided on the piezoelectric substrate. Separate from the through hole above the excitation electrode, through holes extending through the frame and the lid are provided above the pads. These through holes are filled with metal so as to form via conductors. Bumps are provided on these via conductors.

### CITATION LIST

### Patent Literature

Patent Literature 1: International Publication No. 2006/134928
Patent Literature 2: International Publication No. 2017/179574

### SUMMARY

According to an embodiment of the present disclosure, an electronic component includes a chip, an intermediate member, a lid, and a bonding member. The chip has a first surface and includes a functional part and a terminal. The functional part occupies a portion of the first surface and is configured to vibrate. The terminal occupies another portion of the first surface and is electrically connected to the functional part. The intermediate member is stacked on the first surface. The intermediate member includes, above the functional part, a first through hole extending through the intermediate member in a direction in which the first surface faces and thereby surrounds the functional part when the first surface is viewed in plan view. The lid is stacked on a surface of the intermediate member on an opposite side from the chip and closes the first through hole. The bonding member is electrically conductive. The bonding member is electrically connected to the terminal and includes a portion located on an opposite side of the lid from the intermediate member. The intermediate member surrounds the terminal as well as the functional part when the first surface is viewed in plan view as a result of the first through hole being located above the terminal as well as above the functional part. The lid includes a second through hole extending through the lid in a direction in which the first surface faces at a position overlapping the terminal out of the functional part and the terminal when the first surface is viewed in plan view. The bonding member includes a portion located on an opposite side of the second through hole from the intermediate member, a portion located inside the second through hole, and a portion located inside the first through hole and bonded to the terminal.

According to an embodiment of the present disclosure, an electronic device includes the above-described electronic component, a mounting substrate, and a sealing portion. The mounting substrate has a mounting surface and includes a pad. The mounting surface faces a side of the electronic component where the lid is located. The pad occupies a portion of the mounting surface and is bonded to the bonding member. The sealing portion covers at least a portion of an outer peripheral surface of the chip on a side near the mounting surface and closely contacts the mounting surface.

According to an embodiment of the present disclosure, a method of manufacturing the above-described electronic component includes a bonding step and a bonding member disposing step. In the bonding step, the chip, the intermediate member, and the lid are bonded to each other. In the bonding member disposing step, after the bonding step, the bonding member, in a molten state, is supplied into the second through hole and bonds to the terminal.

### BRIEF DESCRIPTION OF THE DRAWINGS

FIG. 1 is a perspective view illustrating the exterior of an electronic component according to an embodiment.

FIG. 2 is a perspective view of the electronic component in FIG. 1 with a lid removed.

FIG. 3 is a cross-sectional view taken along line in FIG. 1.

FIG. 4 is an enlarged view of a region IV in FIG. 3.

FIG. 5 is an enlarged view of a region V in FIG. 4.

FIG. 6 is a flowchart illustrating the steps of a method of manufacturing the electronic component in FIG. 1.

FIG. 7 is a cross-sectional view supplementing the flowchart in FIG. 6.

FIGS. 8A, 8B, and 8C are cross-sectional views supplementing the flowchart in FIG. 6.

FIG. 9 is a schematic cross-sectional view of an electronic device according to an embodiment.

FIG. 10 is a cross-sectional view of the configuration in the vicinity of bonding member of an electronic component according to a variation.

### DESCRIPTION OF EMBODIMENTS

Hereafter, embodiments according to the present disclosure will be described in detail while referring to the drawings. The drawings used in the following description are schematic drawings, and the proportions of the dimensions and so forth in the drawings do not necessarily correspond to the actual proportions of the dimensions and so forth.

Although any direction may be regarded as being up or down in relation to an electronic component of the present disclosure, for convenience, a Cartesian coordinate system consisting of axes D1, D2, and D3 is defined and the positive side of the axis D3 may be referred to as “up” and terms such as “upper surface” and “lower surface” may be used hereinafter. Terms such as “plan view” or “planar see-through view” mean looking in a direction parallel to the axis D3 unless otherwise noted.

(Overall Configuration of Electronic Component)

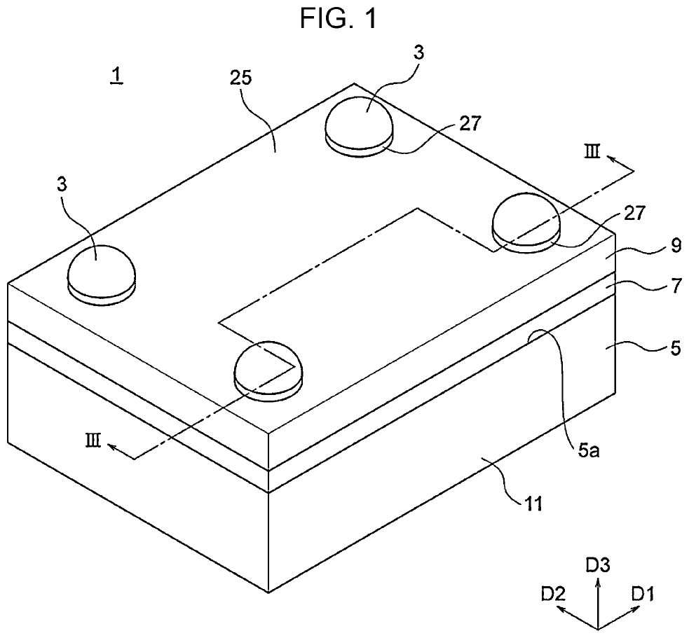

FIG. 1 is an external perspective view of an electronic component 1 according to an embodiment.

The electronic component 1 is configured as a so-called wafer-level package (WLP) type chip component. The electronic component 1 has, for example, a substantially thin rectangular parallelepiped shape (rectangular parallelepiped shape having a thickness that is smaller than the lengths of the sides thereof in plan view. This applies similarly elsewhere below). The dimensions of the electronic component 1 may be set as appropriate. As specific examples of the dimensions, the length of one side in plan view (in a direction along the axis D1 or D2) is not less than 0.5 mm and not more than 2 mm, and the thickness (in a direction along the axis D3) is not less than 0.2 mm and not more than 0.6 mm (however, the thickness is smaller than the lengths in the directions along the axes D1 and D2).

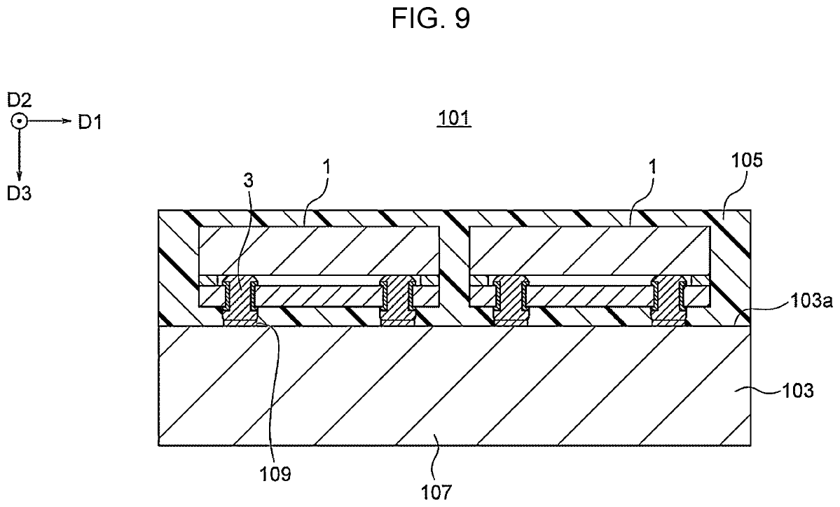

A plurality (four in the illustrated example) of bonding members 3 is exposed on the upper surface of the electronic component 1. The bonding members 3 are composed of an electrically conductive material such as solder and are electrically connected to elements inside the electronic component 1. The bonding members 3, for example, constitute bumps protruding from the upper surface of the electronic component 1. Thus, for example, the electronic component 1 can be surface mounted by bonding the bumps to a circuit board (refer to, for example, a mounting substrate 103 in FIG. 9 described below).

The electronic component 1 includes, for example, a chip 5, an intermediate member 7 stacked on an upper surface 5a of the chip 5, and a lid 9 stacked on the upper surface of the intermediate member 7. The chip 5 corresponds to a bare chip of a WLP-type chip component and directly serves as an electronic element. The intermediate member 7 and the lid 9, together with the bonding members 3, constitute the package of the WLP-type chip component and contribute to sealing the chip 5 and electrically connecting the chip 5 to the outside (for example, to a circuit board).

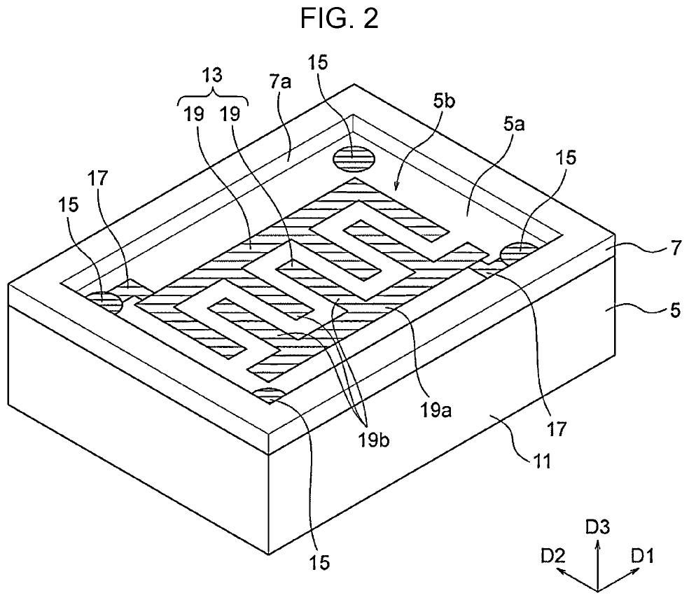

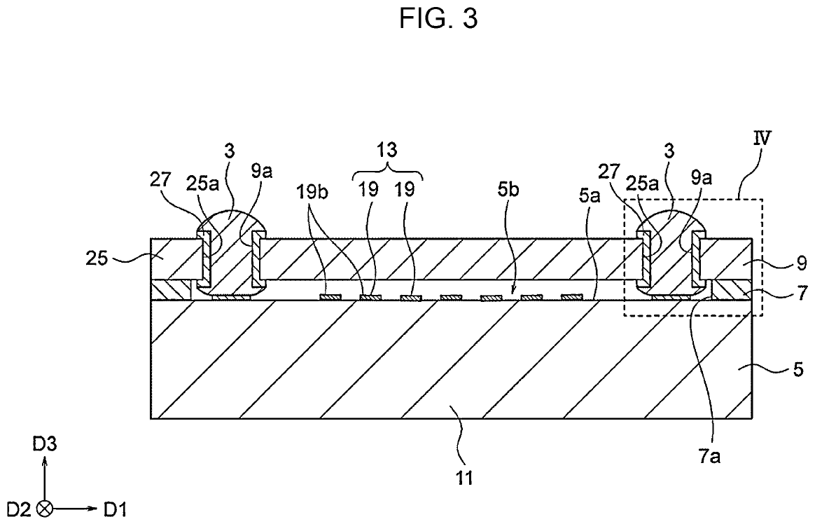

FIG. 2 is a perspective view of the electronic component 1 illustrated with the lid 9 having been removed. FIG. 3 is a cross-sectional view taken along line in FIG. 1.

The chip 5 includes a functional part 5b located on the upper surface 5a. The functional part 5b is electrically connected to the bonding members 3. The functional part 5b is input with electrical signals via the bonding members 3 and/or outputs electrical signals via the bonding members 3. The functional part 5b generates vibrations in response to electrical signals input thereto and/or output therefrom.

The intermediate member 7 includes a frame part surrounding the functional part 5b in plan view. In other words, the intermediate member 7 includes, above the functional part 5b, a through hole 7a that extends through the intermediate member 7 in a direction in which the upper surface 5a faces. The lid 9 closes the through hole 7a from above. Therefore, an airtight space (reference symbol omitted) enclosed by the upper surface 5a, the inner peripheral surface of the through hole 7a, and the lower surface of the lid 9 is formed above the functional part 5b. This space contributes to facilitating vibration of the functional part 5b. The space may be in a vacuum state or may be filled with an appropriate inert gas (for example, nitrogen).

As illustrated in FIG. 3, the lid 9 includes a plurality of through holes 9a that connect the through hole 7a to the space outside the electronic component 1. The bonding members 3 are partially located inside the through holes 9a and inside the through hole 7a, and are bonded to the chip 5. Thus, the bonding members 3 and the chip 5 are electrically connected to each other. Thus, one feature of the electronic component 1 is that the bonding members 3, which constitute bumps for surface mounting, are partially located inside the through hole 7a in order to facilitate vibration of the functional part 5b, and are thus directly electrically connected to the chip 5.

(Chip)

The shape and dimensions of chip 5 may be set as appropriate. For example, the chip 5 has a substantially thin rectangular parallelepiped shape. The shape and dimensions of the chip 5 in plan view are substantially the same as the shape and dimensions of the electronic component 1 in plan view. The thickness of the chip 5 may be greater than or equal to half the thickness of the electronic component 1 (illustrated example) or less than or equal to half the thickness of the electronic component 1. Although not specifically illustrated, the chip 5 may have step portions on the side surfaces thereof.

In this embodiment, a SAW chip utilizing SAWs is used as an example of the chip 5. The chip 5, which is a SAW chip, includes, for example, an element substrate 11 and a conductor layer located on the upper surface of the element substrate 11. The conductor layer includes, for example, at least one (only one is illustrated in FIGS. 2 and 3) excitation electrode 13, a plurality of (four in FIG. 2) terminals 15, and wirings 17 connecting the excitation electrode 13 and the terminals 15 to each other.

Although not specifically illustrated, the chip 5 may further include an insulating layer that covers the upper surface of element substrate 11 from above the excitation electrode 13 while leaving the terminals 15 exposed. Such an insulating layer may be simply used to reduce corrosion of the excitation electrode 13, or may have an acoustically advantageous effect. The material of such an insulating layer may be any suitable material, for example, SiO₂.

The upper surface 5a of the chip 5 consists of, for example, the upper surface of the element substrate 11 and the conductor layer (the excitation electrode 13 and so forth) stacked on the upper surface. If an insulating layer covering the upper surface of the element substrate 11 is provided above the excitation electrode 13 as described above, the upper surface 5a will also include that insulating layer. The functional part 5b consists of the region of the upper surface 5a where the excitation electrode 13 is disposed.

(Element Substrate)

The shape and dimensions of the element substrate 11 are substantially the same as or similar to the shape and dimensions of the chip 5, for example. Therefore, the description of the shape and dimensions of chip 5 described above may also be applied to the shape and dimensions of element substrate 11.

The element substrate 11 is composed of a piezoelectric body at least in the region of the upper surface where the functional part 5b is formed. The piezoelectric body is composed of, for example, a single crystal having piezoelectric properties. The single crystal is, for example, quartz (SiO₂), a lithium niobate (LiNbO₃) single crystal, or a lithium tantalate (LiTaO₃) single crystal. The cut angle may be set as appropriate in accordance with the type of SAWs utilized.

The element substrate 11 may, for example, be entirely composed of a piezoelectric body (i.e., may be a piezoelectric substrate), may be realized by forming a piezoelectric layer on a support substrate composed of an appropriate material, or may consist of a piezoelectric substrate and a support substrate bonded together. The side surfaces and bottom surface of the element substrate 11 may be covered by an insulating layer or the like having a smaller thickness than the element substrate 11.

(Excitation Electrode, Wirings, and Terminals)

The excitation electrode 13 is a so-called interdigital transducer (IDT) and includes a pair of comb electrodes 19. Each comb electrode 19 includes a bus bar 19a and a plurality of electrode fingers 19b extending from the bus bar 19a. The pair of comb electrodes 19 are arranged so as to mesh with each other (so that the electrode fingers 19b cross each other).

FIGS. 2 and 3 are schematic diagrams and therefore only a few electrode fingers 19b of each comb electrode 19 are illustrated. In reality, a larger number of electrode fingers 19b than illustrated may be provided. In FIGS. 2 and 3, a standard shape is illustrated as the shape of the excitation electrode 13. Unlike in the illustration, the excitation electrode 13 may be a so-called apodized electrode, so-called dummy electrodes may be provided, and the bus bars 19a may be inclined with respect to the propagation direction of SAWs.

Since FIGS. 2 and 3 are schematic diagrams, only one excitation electrode 13 is illustrated. In reality, a plurality of excitation electrodes 13 may be provided. Reflector electrodes may be provided on both sides of the excitation electrode 13 in the propagation direction of SAWs (direction D1 in FIG. 3). One or more excitation electrodes 13 may constitute, for example, a SAW resonator, a ladder-type resonator filter, a dual or multiple mode resonator filter, and/or a splitter.

When an electrical signal is input to the excitation electrode 13, the electrical signal is converted into SAWs and the SAWs propagate along the upper surface of the element substrate 11 in a direction (direction D1) perpendicular to the electrode fingers 19b. The SAWs are converted into an electrical signal by the excitation electrode 13 that excited the SAWs or by another excitation electrode 13. In this way, the functional part 5b vibrates and also functions as a resonator or a filter.

The numbers, positions, and so on of the terminals 15 and the wirings 17 may be set as appropriate in accordance with the number, arrangement, and so on of the one or more excitation electrodes 13. In the illustrated example, four terminals 15 are provided adjacent to the four corners of the element substrate 11. In addition, although not specifically illustrated, the terminals 15 may be provided adjacent to the outer edges of the element substrate 11 at positions spaced away from the four corners of the element substrate 11, or the terminals 15 may be provided so as to be spaced away from the outer edges of the element substrate 11. The term “adjacent” used here may be, for example, defined as meaning that the minimum distance between the terminals 15 and the corners or outer edges of the element substrate 11 is less than ¼ or less than 1/10 of the length of the long sides of the element substrate 11.

In the example in FIG. 2, only two of the four terminals 15 are connected to the excitation electrode 13, and the other two terminals 15 are in an electrically floating state. Such electrically floating terminals 15 (dummy terminals) do not have to be provided. In general, in an actual SAW chip, all of the terminals 15 are each electrically connected to one of the one or more excitation electrodes 13. In this description, unless otherwise noted, basically, the terminals 15 are electrically connected to the excitation electrode 13 (in other words, the functional part 5b).

The planar shape of terminals 15 may be chosen as appropriate. For example, the planar shape of terminals 15 may be a circular shape (illustrated example), an oval shape, a rectangular shape, or a polygonal shape other than a rectangular shape. In the present disclosure, with respect to the shape of the terminals 15 and other components, polygonal shapes such as rectangular shapes may include shapes having chamfered corners, unless otherwise noted.

The excitation electrode 13, terminals 15, and the wirings 17 (conductor layer stacked on the upper surface of the element substrate 11) are composed of an appropriate metal, such as an Al—Cu alloy. These components may be composed of the same material as each other or may be composed of different materials from each other. Each of these components may be composed of one material, or may be composed of a plurality of materials, for example, a plurality of layers of different materials stacked on top of each other. The terminals 15 may each include a layer composed of the same material as the material of the excitation electrode 13 and the wirings 17, and a layer composed of another material covering the first layer.

(Intermediate Member)

The intermediate member 7 contributes to forming a sealed space above the functional part 5b. In other words, the intermediate member 7 plays a structural role and does not directly play an electrical role. No distinction may be made between the upper surface and the lower surface of the intermediate member 7 (either surface may be the surface near the chip 5 or the surface near the lid 9) (illustrated example), or a distinction may be made between the upper and lower surfaces.

Although not specifically illustrated, unlike in the present embodiment, the intermediate member 7 may have an electrical role. For example, the intermediate member 7 may include electrical elements (for example, resistors, capacitors, and inductors) composed of conductors located on a surface thereof and/or thereinside. This electrical elements may, for example, be electrically connected to the functional part 5b of the chip 5 via wirings (conductor layers and/or via conductors) of the intermediate member 7 and wirings on the upper surface 5a of the chip 5. For example, the intermediate member 7 may include a conductor pattern serving as a shield.

The intermediate member 7 is bonded to the upper surface 5a of the chip 5, for example. More specifically, part or the entirety of the intermediate member 7 may be bonded to the upper surface of the element substrate 11, to an insulating layer, which is not illustrated, covering the upper surface of the element substrate 11 from above the excitation electrode 13, or to a conductor layer on the element substrate 11 (for example, wiring or a shield of the conductor layer).

The intermediate member 7 is itself bonded to the upper surface 5a of the chip 5 so as to closely contact the upper surface 5a. The intermediate member 7 is also similarly bonded to the lid 9. Therefore, the intermediate member 7 may be regarded as being a bonding member bonding the chip 5 and the lid 9 to each other. However, there may be an adhesive layer interposed between the intermediate member 7 and the chip 5 and/or between the intermediate member 7 and the lid 9. However, such an adhesive layer may be regarded as being part of the intermediate member 7.

(Shape of Intermediate Member)

The intermediate member 7 is, for example, shaped like a layer (including a plate-like shape) of an approximately constant thickness through which the through hole 7a penetrates in the thickness direction. In plan view, the shape and dimensions of the outer edges of the intermediate member 7 are approximately the same as the shape and dimensions of the electronic component 1 in plan view, for example. The thickness of the intermediate member 7 may be set as appropriate. For example, the thickness of the intermediate member 7 is smaller than the thickness of the element substrate 11. As an example, a specific numerical value of the thickness of the intermediate member 7 is not less than 10 μm and not more than 50 μm.

In the example in FIGS. 2 and 3, only one through hole 7a is provided. However, a plurality of through holes 7a may be provided. For example, in a mode where a plurality of excitation electrodes 13 is provided, only one functional part 5b may be defined within the upper surface 5a of the chip 5 so as to encompass all of the plurality of excitation electrodes 13 (and reflector electrodes) or a plurality of functional parts 5b may be defined within the upper surface 5a that each include one or more excitation electrodes 13. In the latter case, a plurality of through holes 7a may be provided in an individual manner for the plurality of functional parts 5b. In a mode where a plurality of through holes 7a is provided, the description relating to the through hole 7a in this embodiment may be applied to only one through hole 7a, or to two or more and/or all the through holes 7a so long as no inconsistencies arise.

The through hole 7a overlaps the one or more functional parts 5b and the one or more terminals 15 in plan view. In the illustrated example, there is one functional part 5b, but the through hole 7a may be regarded as overlapping the whole functional part 5b and all the terminals 15. In a mode where a plurality of through holes 7a is provided, in addition to the through hole 7a overlapping the functional part 5b and the terminals 15, there may be a through hole 7a overlapping only another functional part 5b and/or only another terminal 15.

The specific shape and dimensions of the through hole 7a may be set as appropriate. For example, in plan view, the shape of the through hole 7a may be a polygonal shape (for example, a rectangular shape), or a circular shape or an oval shape. In the illustrated example, the through hole 7a is shaped so as to have an edge located inward at a certain distance from the outer edge of the intermediate member 7 (the outer edge of the element substrate 11 from another perspective). In other words, the intermediate member 7 is rectangular and frame-shaped and has four sides extending substantially along the outer edge of the element substrate 11 with a certain width. The width of the parts (edges) of the intermediate member 7 that extend so as to form the frame may be set as appropriate. For example, the width may be greater than, equal to, or less than the thickness of the intermediate member 7. As an example, a specific numerical value of the width is not less than 10 μm and not more than 50 μm.

For example, in the longitudinal cross section illustrated in FIG. 3, the inner surface of the through hole 7a is generally perpendicular to the upper surface of the element substrate 11. In other words, the shape and dimensions of the through hole 7a in a lateral cross section parallel to the upper surface of the element substrate 11 are generally constant regardless of the position in the height direction (direction D3). However, unlike in the illustrated example, the shape and dimensions of the lateral cross section of the through hole 7a do not have to be constant. For example, the through hole 7a may have a shape in which the diameter increases or decreases with increasing proximity to the element substrate 11, or may have a shape having a maximum or minimum diameter at a position at the center in the direction D3.

(Material of Intermediate Member)

The material of the intermediate member 7 is, for example, an insulating material. The insulating material may be an organic material, an inorganic material, or a combination of both an organic material and an inorganic material. The material of the intermediate member 7 may be a composite material that includes a base material (matrix) and a reinforcing material located within the base material. The material of the base material may be an organic or inorganic material. The material of the reinforcing material may be an organic or inorganic material. The reinforcing material may be in the form of fibers, whiskers (branching or needle-like substances), particles (filler), or a combination of two or more of these forms. Whiskers may be classified as fibers or particles. The fibers may be in the form of a cloth (woven or non-woven) but do not have to be in the form of a cloth.

From another perspective, the material of the intermediate member 7 may be but does not have to be composed of the same material as a printed wiring board (more specifically, the insulating substrate thereof). The printed wiring board, for example, is composed of a composite material in which a base material is impregnated with resin. The resin corresponds to the base material and the base material corresponds to the reinforcing material. The resin and the base material may be those used in known printed wiring boards, or may be applications thereof. For example, the base material may be paper, glass cloth (glass fabric), or synthetic fiber cloth. Only one layer of the base material may be provided or two or more layers of the base material may be provided. As previously mentioned, unlike in the present embodiment, the intermediate member 7 may include electrical elements, and in this mode, the intermediate member 7 may be the same as or similar to a printed wiring board (insulating substrate and conductors).

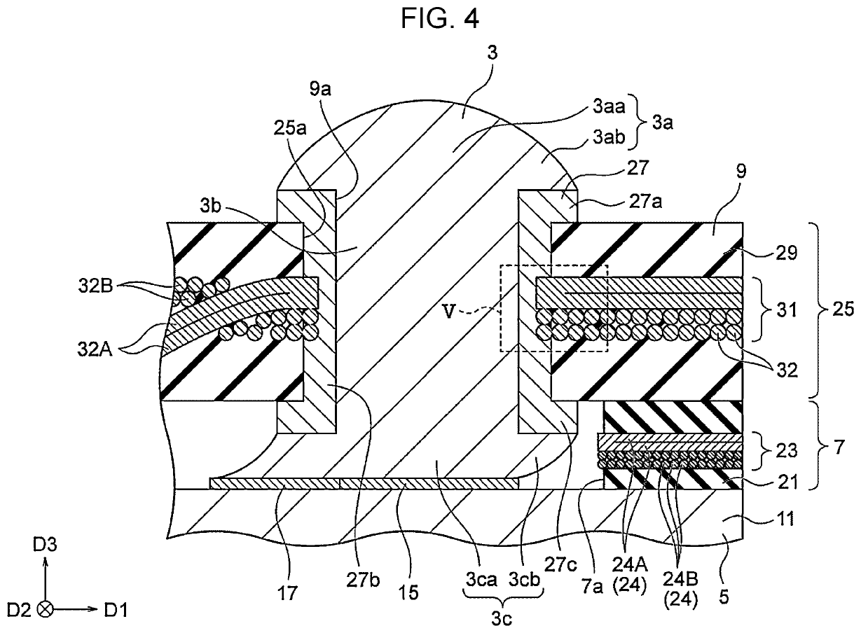

FIG. 4 is an enlarged view of a region IV in FIG. 3.

In the illustrated example, the intermediate member 7 is composed of a composite material including a base material 21 and a reinforcing material 23. The base material 21 is, for example, composed of a resin. The reinforcing material 23 is composed of, for example, glass cloth (from another perspective, glass fibers constituting glass cloth). From another perspective, the intermediate member 7 has a configuration the same as or similar to that of a printed wiring board in which a base material composed of glass cloth is impregnated with resin.

The resin constituting the base material 21 is, for example, a thermosetting resin. The thermosetting resin is, for example, epoxy resin, phenol resin, imide resin (polyimide), bismaleimide triazine resin, or allylated polyphenylene ether. Examples of resins other than thermosetting resins (thermoplastic resins) that may constitute the base material 21 include, for example, tetrafluoroethylene resins, liquid crystal polymers, or polyetheretherketones.

The glass cloth constituting the reinforcing material 23 may be a woven cloth or a non-woven cloth, as described previously, and a woven cloth is illustrated in FIG. 4. The weave of the woven fabric may be an appropriate type of weave such as a plain weave. In the woven fabric illustrated in the figure, fibers 24 extending in the direction D1 (referred to as warp yarns 24A for convenience) and fibers 24 extending in the direction D2 (referred to as weft yarns 24B for convenience) cross each other. More precisely, the warp yarns 24A, every certain number of which are bundled together, and weft yarns 24B, every certain number of which are bundled together, cross each other in an alternating manner at positions above and below each other. However, in FIG. 4, all of the weft yarns 24B are located below the warp yarns 24A due to the fact that the size of the bundle of weft yarns 24B in the direction D1 is larger than the width of one side of the intermediate member 7.

The glass constituting the fiber 24 is, for example, mainly composed of silicate, and may be quartz glass, soda lime glass, or borosilicate glass, for example. The glass has a lower coefficient of linear expansion than, for example, the resin constituting the base material 21. For example, the coefficient of linear expansion of the resin of the base material 21 is 25μ/° C. or higher, whereas the coefficient of linear expansion of the glass of the fibers 24 is not less than 3μ/° C. and not more than 8 μPC. The diameter of the fibers 24 (For example, circle equivalent diameter. Same applies hereafter.) may be set as appropriate. A specific value of the diameter may be, for example, not less than 1 μm and not more than 10

(Lid)

The lid 9 illustrated in FIGS. 1 and 3 forms a sealed space above the functional part 5b and contributes to preserving the bonding members 3. In other words, the lid 9 plays a structural role and does not have a direct electrical role except for the contributing to conduction of the bonding members 3. No distinction may be made between the upper surface and the lower surface of the lid 9 (either surface may be the surface near the intermediate member 7) (as in the illustrated example), or a distinction may be made between the upper and lower surfaces.

However, unlike in the present embodiment, the lid 9 may have an electrical role in addition to contributing to conduction of the bonding members 3. For example, the lid 9 may be provided with an electrical element for example, a resistor, a capacitor, or an inductor) composed of conductors located on a surface of the lid 9 and/or inside the lid 9. This electrical element may, for example, be electrically connected to the functional part 5b of the chip 5 via a wiring (conductor layer and/or via conductor) of the lid 9, a wiring of the intermediate member 7 and/or a wiring on the upper surface 5a of the chip 5. For example, the lid 9 may include a conductor pattern serving as a shield. For example, the lid 9 may include a wiring that connects the bonding members 3, which are supplied with a reference potential, to each other.

The lid 9 includes, for example, an insulating substrate 25 constituting the majority of the lid 9 and conductor layers 27 forming the inner surfaces of the through holes 9a. From another perspective, the lid 9 has the same or a similar configuration to a printed wiring board having through holes. However, unlike in this embodiment, the lid 9 may consist of only the insulating substrate 25. In addition, unlike in this embodiment, as described above, the lid 9 may have an electrical role. In this form, the lid 9 may have a configuration the same as or similar to that of a printed wiring board. A printed wiring board serving as the lid 9 may be a single-sided board provided with conductor layers on only one side of the insulating substrate 25, a double-sided board having conductor layers provided on both sides of the insulating substrate 25, or a multilayer board having conductor layers provided inside the insulating substrate 25 in addition to on both sides of the insulating substrate 25. In the illustrated example, the conductor layers 27 each include portions located on both sides of the insulating substrate 25, and the lid 9 may be regarded as being the same as or similar to a double-sided board.

(Shape of Lid)

The lid 9 is, for example, shaped like a layer (including a plate-like shape) of an approximately constant thickness through which the through holes 9a penetrate in the thickness direction. In plan view, the shape and dimensions of the outer edge of the lid 9 are substantially the same as the shape and dimensions of the electronic component 1 in plan view, for example. The thickness of the lid 9 may be set as appropriate. For example, the thickness of the lid 9 is smaller than the thickness of the element substrate 11. The thickness of the lid 9 may be greater than, equal to, or smaller than the thickness of the intermediate member 7. In the illustrated example, the thickness of the lid 9 is greater than the thickness of the intermediate member 7. More precisely, for example, the thickness of the lid 9 is not less than 1.1 and not more than 5 times or not less than 2 and not more than 3 times the thickness of the intermediate member 7. A specific numerical value of the thickness of the lid 9 is, for example, not less than 20 μm and not more than 100 μm.

The number of through holes 9a is, for example, the same as the number of terminals 15. In other words, multiple through holes 9a are provided in an individual (one-to-one) manner for multiple terminals 15. Each through hole 9a is located directly above the corresponding terminal 15. In other words, in planar see-through view, the openings at the lower planes of the through holes 9a (the portions connected to the through holes 7a) at least partially overlap the terminals 15. Therefore, description of the positions of the plurality of terminals 15 in plan view may be applied to the positions of the plurality of through holes 9a in plan view. In descriptions in which the positions of the terminals 15 in plan view are compared with the shape of the element substrate 11, the term “element substrate 11” might or might not be replaced by the term “lid 9”.

Unlike in this embodiment, the number of through holes 9a and the number of terminals 15 do not have to be the same. For example, if bonding members 3 (through holes 9a) are provided that contribute to bonding the electronic component 1 to a circuit board without contributing to electrical conduction, dummy terminals 15 do not have to be provided directly below the bonding members 3.

The through holes 9a, for example, extend through the lid 9 in straight lines in a direction perpendicular to a main surface of the lid 9. Unlike in this embodiment, the through holes 9a may be inclined or bent with respect to a direction perpendicular to a main surface of the lid 9.

The shape of a lateral cross section of the through holes 9a (cross section perpendicular to the direction of extension, or, from another perspective, parallel to the main surface of the lid 9) may be chosen as appropriate. For example, the shape of the lateral cross section of the through holes 9a may be a circular shape (example illustrated in the figure), an oval shape, a rectangular shape, or a polygonal shape other than a rectangular shape. The shape and/or dimensions of the lateral cross section of the through holes 9a are, for example, generally constant regardless of the position in the direction in which the through holes 9a extend. However, unlike in the illustrated example, the shape and dimensions of the lateral cross section of the through holes 9a do not have to be constant. For example, the through holes 9a may be shaped so as to have a diameter that increases or decreases in an upward direction, or may have a maximum or minimum diameter at a position in the center in the direction D3.

The dimensions of the lateral cross sections of the through holes 9a may be set as appropriate. For example, in plan view, the outer edge of the opening at the lower plane of each through hole 9a (the portion connected to the through hole 7a) may entirely coincide with the outer edge of the corresponding terminal 15 (illustrated example), may be entirely located inside the outer edge of the terminal 15, may be partially located outside the terminal 15, or may be entirely located outside the terminal 15. Even when it is stated that the outer edges coincide, it is of course possible that allowances and the like exist. For example, in planar see-through view, if the areas of the portions of the through hole 9a and the terminal 15 that do not overlap each other are less than 10% of the areas of the portions of the through hole 9a and the terminal 15 that do overlap each other, the through hole 9a and the terminal 15 may be considered to have the same shape and dimensions.

(Insulating Substrate)

The insulating substrate 25 constitutes the majority of the lid 9. Thus, basically, the above description relating to the shape and dimensions of the lid 9 may also be applied to the shape and dimensions of the insulating substrate 25.

The insulating substrate 25 contains through holes 25a that form the through holes 9a in which the bonding members 3 are disposed. The through holes 9a are formed by the conductor layers 27 being deposited on the inner surfaces of the through holes 25a. Descriptions relating to the shape and dimensions of the through holes 9a may be applied to the shape and dimensions of the through holes 25a by subtracting the thickness of the conductor layers 27.

The material of the insulating substrate 25 may be the same as or similar to the material of the insulating substrate of a printed wiring board, for example. The materials of the intermediate member 7 and the insulating substrate 25, which constitute the same electronic component 1, may be the same as or different from each other. In any case, the previous description regarding the material of the intermediate member 7 may be applied to the material of the insulating substrate 25.

For example, the material of the insulating substrate 25 may be an organic material, an inorganic material, or a combination of organic and inorganic materials. The material of the insulating substrate 25 may be a composite material including a base material and a reinforcing material. The base material and reinforcing material may each be an organic material or an inorganic material. The reinforcing material may consist of fibers, whiskers, particles, or a combination of two or more of these forms. The fibers may be in the form of a cloth (woven or non-woven) but do not have to be in the form of a cloth. The base material of the printed wiring board serving as the insulating substrate 25 may consist of paper, glass cloth, or synthetic fiber cloth, and the number of layers of the base material may be chosen as appropriate.

In the example illustrated in FIG. 4, the insulating substrate 25 is composed of a composite material containing a base material 29 and a reinforcing material 31. The base material 29 may be the same as or different from the base material 21 of the intermediate member 7, and the reinforcing material 31 may be the same as or different from the reinforcing material 23 of the intermediate member 7. In any case, the previous description of base material 21 and reinforcing material 23 may be applied to base material 29 and reinforcing material 31 so long as there are no inconsistencies and unless otherwise noted.

For example, the base material 29 is composed of resin. Specific examples of the resin include those given in the description of the base material 21. The reinforcing material 31 is, for example, composed of glass cloth (from another perspective, glass fibers constituting glass cloth). The glass cloth constituting the reinforcing material 31 may be a woven cloth or a non-woven cloth, and a woven cloth is exemplified in FIG. 4. In the woven fabric, for example, fibers 32 extending in the direction D1 (referred to as warp yarns 32A for convenience) and fibers 32 extending in the direction D2 (referred to as weft yarns 32B for convenience) (referred to as warp yarns 32A for convenience) cross each other. The previous description regarding the woven fabric (weave) and the fibers 24 in the intermediate member 7 (materials, coefficients of linear expansion, and so on) may be applied to the woven fabric and the fibers 32 in the insulating substrate 25. On the left side of the sheet in FIG. 4, a part is illustrated where the warp yarns 32A and the weft yarns 32B vertically swap places.

The thickness of the glass cloth serving as the reinforcing material 31 of the insulating substrate 25 may be greater than (example illustrated in the figure), equal to, or smaller than the thickness of the glass cloth serving as the reinforcing material 23 of the intermediate member 7. From another perspective, the diameter of the fibers 32 of the insulating substrate 25 may be greater than, equal to, or smaller than the diameter of the fibers 24 of the intermediate member 7. In the illustrated example, the diameter of fibers 32 is larger than the diameter of the fibers 24. More particularly, for example, the diameter of the fibers 32 is not less than 1.1 times and not more than 5 times the diameter of the fibers 24, or not less than 1.5 times and not more than 2.5 times the diameter of the fibers 24. A specific numerical value of the diameter of the fibers 32 may be, for example, not less than 2 μm and not more than 15 μm. Out of the insulating substrate 25 and the intermediate member 7, the member having a relatively larger fiber diameter and the member having a relatively larger substrate thickness may be the same (example illustrated in the figure) or different.

(Conductor Layer)

The range across which each conductor layer 27 is disposed may be set as appropriate. For example, as indicated in FIG. 4, the conductor layer 27 includes a cylindrical portion 27b overlapping (for example, the entirety of) the inner peripheral surface of the through hole 25a of the insulating substrate 25, a lower flange 27c overlapping a peripheral portion of the through hole 25a on the −D3 side of the insulating substrate 25, and an upper flange 27a overlapping a peripheral portion of the through hole 25a on the +D3 side of the insulating substrate 25. However, unlike in this embodiment, the conductor layer 27 may include only one or two of the above three portions. As has already been mentioned, unlike in this embodiment, the lid 9 may include a conductor layer include wirings, a shield, or electrical elements (resistors, capacitors, inductors, and so on). In such a form, the conductor layer 27 may be connected to another such conductor layer. The boundary between conductor layer 27 and another conductor layer does not have to be clearly defined.

The planar shape of the upper flange 27a (the existence of the through hole 9a is ignored here) may be any suitable shape, for example, a circular shape (example illustrated in the figure), an oval shape, a rectangular shape, or a polygonal shape other than a rectangular shape. The dimensions of the planar shape may also be set as appropriate. A specific numerical value of the diameter (for example, the circle equivalent diameter) of the planar shape is, for example, not less than 20 μm and not more than 400 μm or not less than 50 μm and not more than 200 μm.

The planar shape and dimensions of the lower flange 27c (the presence of the through hole 9a is ignored here) may be the same as (example illustrated in the figure) or different from the planar shape and dimensions of the upper flange 27a. In any case, the above description of the planar shape and dimensions of the upper flange 27a may be applied to the planar shape and dimensions of the lower flange 27c.

Even though the planar shape and dimensions of the upper flange 27a and the lower flange 27c are the same as each other, it is of course possible that allowances may exist. For example, in planar see-through view, if the areas of the portions of these two members that do not overlap each other are less than 10% of the areas of the portions of the two members that do overlap each other, the two members may be considered to have the same shape and dimensions.

The thickness of the conductor layer 27 may be generally constant throughout the entirety thereof (example illustrated in the figure), or the conductor layer 27 may have different thicknesses in different parts thereof. As an example of the latter case, for example, the thickness of the upper flange 27a and/or the thickness of the lower flange 27c may be greater than the thickness of the cylindrical portion 27b, or vice versa. The relationship between the thickness of the conductor layer 27 and the dimensions of the other members may be set as appropriate. In the illustrated example, the thickness of the conductor layer 27 is greater than the thickness of the conductor layer (excitation electrode 13, terminal 15 and wiring 17) located on the upper surface 5a of the chip 5, greater than the diameter of the fibers 32, and smaller than the diameter of the through hole 9a. A specific value of the thickness of the conductor layer 27 is, for example, not less than 1 and not more than 40 μm or not less than 3 μm and not more than 20 μm.

The entirety of the conductor layer 27 may be composed of the same material, or individual portions (for example, 27a, 27b, and 27c) may be made of different materials from each other. All or each portion of the conductor layer 27 may be composed of one material, or a plurality of layers composed of different materials may be stacked on top of each other. The material of the conductor layer 27 may be, for example, a metal, and the specific metal may be chosen as appropriate. For example, a material used for an under-barrier metal forming the surface of a pad to which solder is bonded may be used as the material of the conductor layer 27. One such example is a Ni—Au alloy.

(Bonding Members)

As has been already described, the bonding members 3 illustrated in FIGS. 1, 3, and 4 are composed of solder or the like and contribute to bonding the electronic component 1 to a circuit board or the like. Therefore, the shape of the bonding members 3 changes between before and after mounting, at least in the portions located on the +D3 side of the lid 9. Hereafter, unless otherwise noted, the shape before mounting is described.

As indicated in FIG. 4, each bonding member 3 includes an upper end 3a located on the +D3 side of the lid 9 and constituting a bump, a center portion 3b located inside the through hole 9a of the lid 9, and a lower end 3c located inside the corresponding through hole 7a of the intermediate member 7 and bonded to the terminal 15.

The upper end 3a has, for example, a roughly hemispherical shape. In other words, the surface of the upper end 3a forms a curved surface that bulges towards the +D3 side. The curvature and/or the height from the upper surface of the lid 9 may be set as appropriate. Unlike in the illustrated example, the upper end 3a may be formed in a circular or square cylindrical shape.

The planar shape and dimensions of a lower-surface-side portion of the upper end 3a are, for example, roughly the same as the planar shape and dimensions of the upper flange 27a of the conductor layer 27 (the through hole 9a is ignored here). For example, in planar see-through view, the areas of the portions of these two parts that do not overlap each other are less than 10% of the areas of the portions of these two parts that do overlap each other. Regardless of whether the planar shape and dimensions of these two parts are roughly the same as each other or different from each other, the above description regarding the planar shape and dimensions of the upper flange 27a may be applied to the shape and dimensions of the upper end 3a in plan view.

From another perspective, the upper end 3a has a first portion 3aa located directly above the through hole 9a (or the center portion 3b from another perspective) of the lid 9 and a second portion 3ab located in an area surrounding the through hole 9a out of the surface of the lid 9 on the +D3 side. In other words, in plan view, the diameter of the upper end 3a is larger than the diameter of the through hole 9a. However, unlike in the present embodiment, the upper end 3a may include only the first portion 3aa.

More specifically, the second portion 3ab includes a portion located on the upper surface of the upper flange 27a of the conductor layer 27. In planar see-through view, the outer edge of the lower-surface-side portion of the second portion 3ab may be entirely located inward from the outer edge of the upper flange 27a, may generally coincide with the outer edge (example illustrated in the figure), may be entirely located outward from, or may be located partly inward and partly outward from the outer edge. From another perspective, the second portion 3ab may include a portion in contact with the outer peripheral surface (in other words, the side surface) of the upper flange 27a, may further include a portion in contact with the insulating substrate 25, or might not include such a portion.

The inside of the through hole 9a of the lid 9 is filled by the center portion 3b without any gaps therebetween. Therefore, the previous description relating to the shape and dimensions of the through hole 9a may be applied to the shape and dimensions of the center portion 3b.

The shape of the lower end 3c may be any of various shapes. For example, the lower end 3c may be shaped so as to decrease in diameter in a downward direction (towards the terminal 15) (FIG. 3), or conversely, may be shaped so as to increase in diameter in a downward direction. In other words, the lower end 3c may be tapered on the whole. The lower end 3c may have a maximum diameter at an intermediate position between the through hole 9a of the lid 9 and the terminal 15, or conversely, may have a minimum diameter at the intermediate position. The lower end 3c may be shaped so as to have a generally constant diameter regardless of the position in the vertical direction. In the example illustrated in FIG. 4, the lower end 3c is basically shaped so that the diameter decreases in the downward direction. However, the lower end 3c spreads outward with increasing proximity to the lower side in the direction in which the wiring 17 extends from the terminal 15.

The shape and dimensions of an upper-surface-side portion of the lower end 3c are, for example, roughly the same as the planar shape and dimensions of the lower flange 27c of the conductor layer 27 (the through hole 9a is ignored here). For example, in planar see-through view, the areas of the portions of these two parts that do not overlap each other are less than 10% of the areas of the portions of these two parts that do overlap each other. Regardless of whether or not the planar shapes and dimensions of these two parts are roughly the same as each other or different from each other, the above description regarding the planar shape and dimensions of the lower flange 27c may be applied to the shape and dimensions of the lower surface of the lower end 3c. The shape and dimensions of the upper-surface-side portion of the lower end 3c may be the same as (as in the illustrated example) or different from the shape and dimensions of the lower-surface-side portion of the upper end 3a.

From another perspective, similarly to the upper end 3a, the lower end 3c includes a third portion 3ca located directly below the through hole 9a (or the center portion 3b from another perspective) and a fourth portion 3cb located in an area surrounding the through hole 9a out of the surface of the lid 9 on the −D3 side. In other words, in planar see-through view, the diameter of the lower end 3c is larger than the diameter of the through hole 9a. However, unlike in the present embodiment, the lower end 3c may include only the third portion 3ca.

In more detail, the fourth portion 3cb has a portion located on the lower surface of the lower flange 27c of the conductor layer 27. In planar see-through view, the outer edge of the upper-surface-side portion of the fourth portion 3cb may be entirely located inward from the outer edge of the lower flange 27c, may generally coincide with the outer edge of the lower flange 27c (illustrated example), may be located entirely outward from the outer edge of the lower flange 27c, or may be located partly inward and partly outward from the outer edge of the lower flange 27c. From another perspective, the fourth portion 3cb may include a portion in contact with the outer peripheral surface (in other words, the side surface) of the lower flange 27c, and may further include a portion in contact with the insulating substrate 25, or might not include such a portion.

As has already been described, the lower end 27c is bonded to the terminal 15. In planar see-through view, the outer edge of the lower-surface-side portion of the lower end 27c may be entirely located inward from the outer edge of the terminal 15, may generally coincide with the outer edge of the terminal 15 (example illustrated in the figure, excluding the wiring 17), may be entirely located outward from, or may be located partly inward and partly outward from the outer edge. From another perspective, the lower end 27c may include a portion in contact with the outer peripheral surface (in other words, the side surface) of the terminal 15, and may further include or not include a portion in contact with the element substrate 11. In the illustrated example, the lower end 27c is also bonded to the part of the wiring 17 that is connected to the terminal 15, but there does not have to be this bond.

The material of the bonding members 3 is, for example, solder. The material of the bonding members 3 is a metal having a liquid phase line temperature of less than 450° C. according to Japanese Industrial Standards (JIS). The solder may be lead-containing solder or lead-free solder. Examples of lead-free solders include Sn—Ag—Cu-based, Sn—Zn—Bi-based, Sn—Cu-based, and Sn—Ag—In—Bi-based solders. The bonding members 3 may be composed of a brazing material having a liquid phase line temperature of 450° C. or higher, or an electrically conductive adhesive composed of a resin containing electrically conductive particles.

(Details of Through Holes in Lid)

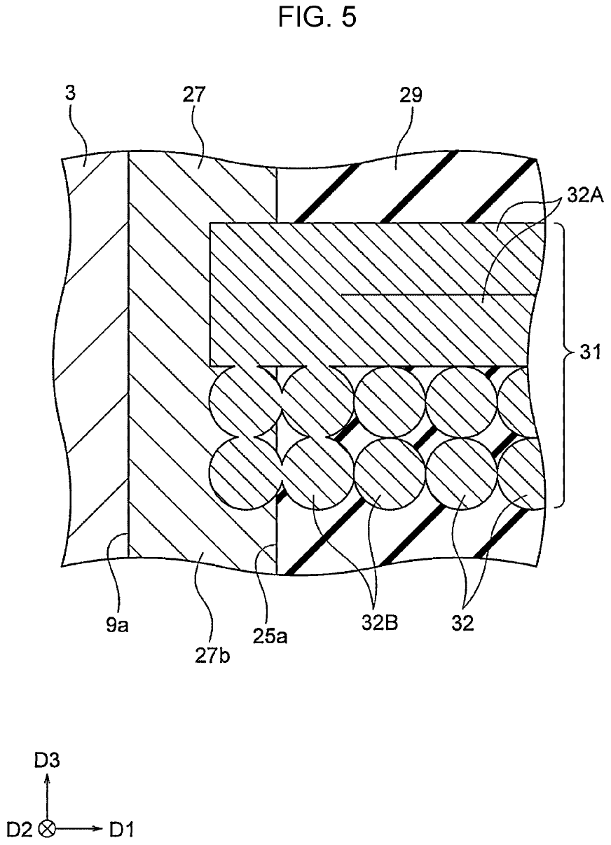

FIG. 5 is an enlarged view of a region V in FIG. 4.

Constituent parts of the reinforcing material (for example, particles or fibers) of the lid 9 may be directly bonded to each other in the vicinity of the inner peripheral surface of the through hole 25a in the insulating substrate 25. For example, mutually adjacent fibers 32 (reinforcing material from another perspective) constituting the glass cloth serving as the reinforcing material 31 may fuse to each other in the vicinity of the inner peripheral surface of the through hole 25a. In the illustrated example, all of the warp yarns 32A and weft yarns 32B are bonded to each other. However, only warp yarns 32A may be bonded to each other, only weft yarns 32B may be bonded to each other, or only there may only be bonding between warp yarns 32A and weft yarns 32B. The portions bonded to each other may be located inward from, outward from, or so as to cross the inner surface of the through hole 25A of the base material 29 of the lid 9, or may be located both inward and outward from the inner surface. The reinforcing material of the lid 9 has been described, but constituent parts of the reinforcing material of the intermediate member 7 may be similarly directly bonded to each other in the vicinity of the inner surface of the through hole 7a. Of course, in the lid 9 and/or the intermediate member 7, the constituent parts of the reinforcing materials do not necessarily have to be bonded to each other in this manner.

The reinforcing material 31 of the lid 9 may enter the of inside the conductor layer 27 (more specifically, the cylindrical portion 27b). In the illustrated example, the glass cloth serving as the reinforcing material 31 is contained in the conductor layer 27. Although both warp yarns 32A and weft yarns 32B are contained in the conductor layer 27 in the illustrated example, it is acceptable for only one of them to be contained in the conductor layer 27. The depth at which the reinforcing material 31 is contained in the conductor layer 27 may be set as appropriate. For example, the depth at which the glass cloth as reinforcing material 31 is contained in the conductor layer 27 may be smaller or larger than the diameter of the fibers 32. The parts of the reinforcing material 31 located inside the conductor layer 27 may partially or completely consist of the parts where the above-described direct bonding occurs. Of course, unlike in the present embodiment, the reinforcing material 31 does not have to be contained in the conductor layer 27.

(Physical Properties of Each Member)

The physical properties of each member (for example, the coefficient of linear expansion) and the relationship between the physical properties of the members may be set as appropriate.

For example, the coefficient of linear expansion of the intermediate member 7 in a planar direction (along the D1-D2 plane. The same applies hereinafter) may be smaller than the coefficient of linear expansion of the lid 9 in a planar direction. The coefficient of linear expansion of the chip 5 in a planar direction may be smaller than the coefficient of linear expansion of the lid 9 in a planar direction. The coefficient of linear expansion of the intermediate member 7 in a planar direction may be smaller than, equal to, or larger than the coefficient of linear expansion of the chip 5 in a planar direction. For example, as specific values of the coefficients of linear expansion in the planar direction, the coefficient of linear expansion of the chip 5 is not less than 5μ/° C. and not more than 8μ/° C., the coefficient of linear expansion of the intermediate member 7 is not less than 3μ/° C. and not more than 6μ/° C., and the coefficient of linear expansion of the lid 9 is not less than 8μ/° C. and not more than 16μ/° C.

For example, the glass transition temperature of the intermediate member 7 may be greater than the glass transition temperature of the lid 9. For example, as specific values, the glass transition temperature of the intermediate member 7 is not less than 250° C. and not more than 270° C., and the glass transition temperature of the lid 9 is not less than 120° C. and not more than 250° C.

In the above description, the coefficient of linear expansion of the lid 9 is affected by the physical properties of both the insulating substrate 25 and the conductor layers 27. However, if it is possible to ignore the effect of the conductor layers 27 (and other conductor layers), the coefficient of linear expansion of the insulating substrate 25 may be referred to instead of the coefficient of linear expansion of the lid 9. The same applies when the intermediate member 7 includes a conductor layer. Similarly, the coefficient of linear expansion of the element substrate 11 may be referred to for the chip 5. For example, a method specified by JIS, such as a thermo-mechanical analysis method (TMA method), may be employed as a method for measuring the coefficient of linear expansion.

The coefficient of linear expansion has been discussed, but the same applies to the glass transition temperature. That is, the glass transition temperature may be specified on the basis of the behavior (for example, changes in mechanical properties) of a member including an insulator and a conductor with respect to changes in temperature. If the effect of conductors can be ignored, the glass transition temperature of the insulator may be referred to. The glass transition temperature may be measured using a method specified by JIS such as a TMA method.

(Method of Manufacturing Electronic Component)

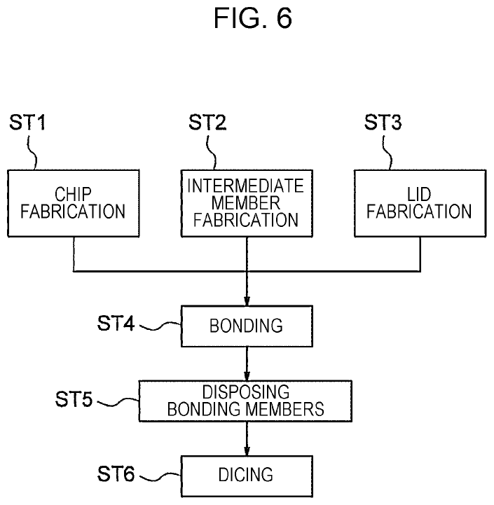

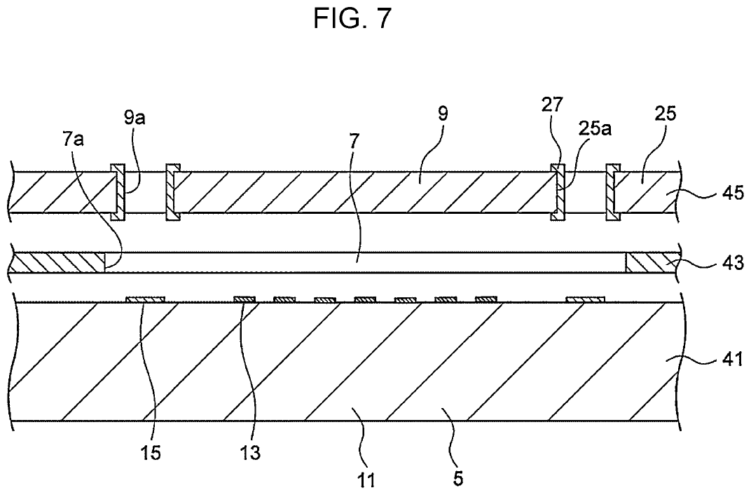

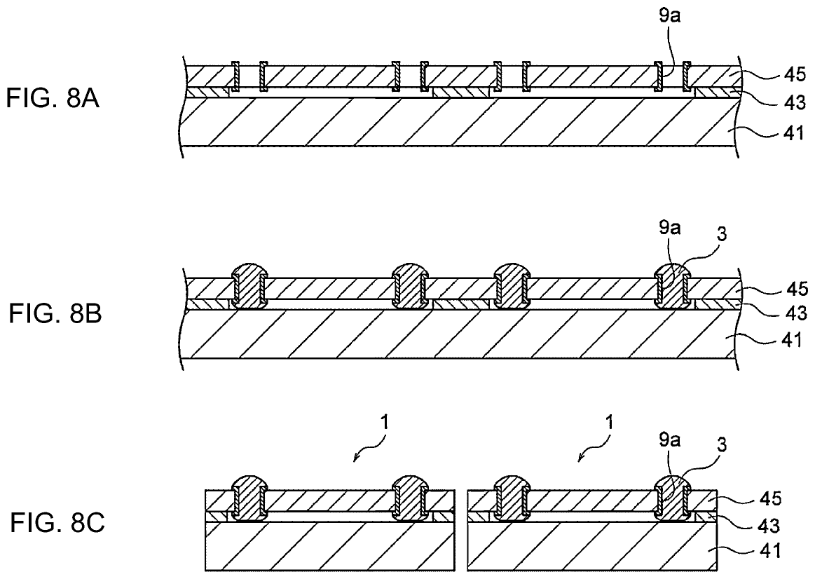

FIG. 6 is a flowchart illustrating the steps of a method of manufacturing an electronic component. FIGS. 7 and 8A to 8C are schematic cross-sectional views supplementing FIG. 6. As the manufacturing method progresses, the states and shapes of the materials constituting the electronic component 1 change, but the same reference symbols may be used before and after the changes.

In Steps ST1 to ST3, the chip 5, the intermediate member 7, and the lid 9 are fabricated in parallel, as illustrated in FIG. 7. In these steps, however, each component is in a state (wafer state) that exists prior to being cut into individual pieces. In FIG. 7, only an area slightly larger than the area of one electronic component 1 is illustrated. In FIGS. 8A to 8B, only an area slightly larger than the area of two electronic components 1 is illustrated.

Specifically, for example, in Step ST1, deposition and patterning of conductors are performed in order to form the excitation electrodes 13, the terminals 15 and so on a wafer from which a large number of device substrates 11 are to be produced. In this way, a chip wafer 41 from which a large number of chips 5 are to be produced is fabricated. The deposition and patterning of conductors may be performed, for example, by etching the deposited conductors through a mask or by depositing conductors through a mask (the same applies hereinafter).

In Step ST2, the through holes 7a are formed in an insulating wafer. As a result, an intermediate wafer 43 from which a large number of intermediate members 7 are to be produced is fabricated. The fabrication of the insulating wafer may be the same as or similar to a method of fabricating a wafer from which a large number of printed wiring boards (insulating substrates) are produced, for example. At the time of Step ST2, the intermediate member 7 may be in a semi-cured state (uncured state, prepreg state). For example, the glass cloth serving as the reinforcing material 23 is soaked in a thermosetting resin, the glass cloth is allowed to become impregnated with the resin, and the impregnated resin is then dried so as to become so-called B-stage resin.

In Step ST3, the through holes 25a are formed in an insulating wafer from which a large number of insulating substrates 25 are to be produced, and then the conductor layers 27 are deposited and patterning is performed. Thus, a lid wafer 45 is fabricated from which a large number of lids 9 are to be produced. The specific fabrication method used may be the same as or similar to a fabrication method used for printed wiring boards. For example, the insulating substrate 25 may be fabricated by soaking the glass cloth serving as the reinforcing material 31 in a thermosetting resin, allowing the glass cloth to be impregnated with the resin, and then curing the impregnated resin. In contrast to Step ST2, the resin of the insulating substrate 25 may be in a fully cured state (so-called C-stage resin).

The formation of the through hole 7a in Step ST2 and the formation of the through holes 25a in Step ST3 may be carried out using an appropriate method such as one employing a laser or punching. When through holes are formed using a laser, typically, the base material (for example, resin) tends to disappear before the reinforcing material (for example, glass cloth). Consequently, the reinforcing material tends to protrude from the base material around the through holes. As a result, in the lid 9, the reinforcing material is likely to penetrate into the conductor layers 27. In the case where the through holes are formed using a laser, the reinforcing material (for example, glass fiber) can be melted around the through holes and parts thereof bond to each other.

After that, in Step ST4, the chip wafer 41, the intermediate wafer 43, and the lid wafer 45 are stacked and bonded to each other as illustrated in FIG. 8A. For example, the intermediate wafer 43 is in a prepreg state as described above, and therefore the three components are stacked on top of each other and heated while pressure is applied to the stacked body. The three components are then bonded together as the resin in the intermediate wafer 43 changes from a semi-cured state to a cured state.

In Step ST5, as illustrated in FIG. 8B, the bonding members 3 are disposed in the bonded wafer multilayer body and bonded to the terminals 15. Specifically, for example, the bonding members 3 in a liquid state are supplied from above the through holes 9a and/or upper flanges 27a using a dispenser. In addition, for example, a conductive paste, which will form the bonding members 3, is supplied from above the through holes 9a and/or the upper flange 27a by screen printing, and then heated to change the conductive paste into a liquid state. The liquid bonding members 3, for example, flow across the surfaces of the conductor layers 27 so as to wet the surfaces of the conductor layers 27. Consequently, the bonding members 3 fill the through holes 9a, reach the lower surfaces of the lower flanges 27c, and contact the terminals 15. The bonding members 3 also accumulate on the upper surfaces of the upper flanges 27a and form bumps.

If the diameter of the through holes 9a is very large and the length of the through hole 7a in the direction D3 is very large, the bonding members 3 might not stay inside the through holes 9a and may flow down into the through hole 7a resulting in disconnections. Conversely, if the diameter of the through holes 9a is extremely small, the bonding members 3 are unlikely to flow into the through holes 9a and reach the terminals 15. By actually fabricating the electronic component 1 according to the embodiment, the applicants confirmed that the above-mentioned issues do not arise when the dimensions exemplified in the embodiment are adopted and when commonly used solder is employed as the bonding members 3.

Step ST5 is performed, for example, under a vacuum atmosphere or an inert gas (e.g., nitrogen) atmosphere. As a result, the through hole 7a of the intermediate member 7 is sealed under a vacuum state or in a state where an inert gas is present.

In Step ST6, the multilayer body consisting of the chip wafer 41, the intermediate wafer 43, and the lid wafer 45 is diced into individual pieces, as illustrated in FIG. 8C. As a result, the individual electronic components 1 are obtained.

Each step may be performed in the same factory or in different factories, and distribution of materials may occur between the steps. For example, Steps ST1, ST2, and ST3 may be performed in different factories from each other. In this case, the prepreg that will become the intermediate member 7 may be distributed while in a semi-cured state by being sealed and temperature-controlled, or the like. An example in which the intermediate member 7 functions as a bonding member is described above, but as already mentioned, an adhesive may be interposed between the intermediate member 7 and the lid 9, and between the intermediate member 7 and the chip 5. In this case, the intermediate member 7 does not have to be kept in a semi-cured state in Step ST2.

### Example of Application of Electronic Component

FIG. 9 is a schematic cross-sectional view of an electronic device 101, which is an application of the electronic component 1. In the description of FIG. 9, the upper side of the sheet in FIG. 9 may be regarded as up.

The electronic device 101 includes, for example, a mounting substrate 103, the electronic components 1 mounted on the mounting substrate 103, and a sealing portion 105 that seals the electronic component 1. The electronic device 101 may be configured, for example, as a filter, a splitter, or a communication device, including a resonator or filter formed by the electronic components 1.

In the illustrated example, two electronic components 1 are mounted on the mounting substrate 103. However, the number of electronic components 1 mounted on the mounting substrate 103 may be chosen as appropriate and may be one or three or more. In addition to the electronic components 1, other components may be mounted on the mounting substrate 103. The other components may be sealed together with the electronic component 1 by the sealing portion 105. The other electronic components may be, for example, integrated circuits (ICs), resistors, capacitors, inductors, and sensors (for example, temperature sensors).

The mounting substrate 103 may be, for example, a known printed wiring board or an application of a known printed wiring board. One of the main surfaces of the mounting substrate 103 is a mounting surface 103a on which the electronic components 1 are mounted. The other main surface of the mounting substrate 103 may be, for example, a surface provided with terminals for mounting the electronic device 101 on another circuit board, which is not illustrated, or may be another mounting surface on which other components are mounted. The mounting substrate 103 includes an insulating substrate 107 and pads 109 located on one main surface of the insulating substrate 107. The bonding members 3 are bonded to the pads 109.

The sealing portion 105 covers at least part of the mounting surface 103a side of the outer peripheral surface of each chip 5 and closely contacts the mounting surface 103a. This, for example, reinforces the sealing of the functional parts 5b. In the illustrated example, the sealing portion 105 covers the mounting surface 103a from above the electronic components 1. In other words, the sealing portion 105 contacts the surfaces of the electronic components 1 on the −D3 side, the outer peripheral surfaces of the electronic components 1, and the mounting surface 103a around the peripheries of the electronic components 1. Furthermore, in the illustrated example, the space between the electronic components 1 and the mounting surface 103a is also filled with the sealing portion 105. Unlike in the illustrated example, the space between the electronic components 1 and the mounting surface 103a does not have to be filled with the sealing portion 105 or the surfaces of the electronic components 1 on the −D3 side do not have to be covered by the sealing portion 105.

The material of the sealing portion 105 may be an organic material, an inorganic material, or a combination of an organic material and an inorganic material. The organic material is, for example, a resin. The inorganic material is composed, for example, ceramic particles bonded together in an amorphous state. The resin may contain particles (filler) composed of an inorganic material. The sealing portion 105 may consist of a sheet covering the electronic components 1 and a material covering the sheet. The physical properties of the sealing portion 105 may also be set as appropriate. As specific values, the coefficient of linear expansion is not less than 12μ/° C. and not more than 20μ/° C., and the glass transition temperature is around 120° C.

As described above, the electronic component 1 includes the chip 5, the intermediate member 7, the lid 9, and the electrically conductive bonding members 3. The chip 5 has a first surface (upper surface 5a), the functional part 5b that occupies part of the upper surface 5a and vibrates, and the terminals 15 that occupy other parts of the upper surface 5a and are electrically connected to the functional part 5b. The intermediate member 7 is stacked on the upper surface 5a. The intermediate member 7 includes, above the functional part 5b, a first through hole (through hole 7a) that extends through the intermediate member 7 in the direction in which the upper surface 5a faces, and thereby surrounds the functional part 5b when the upper surface 5a is viewed in plan view. The lid 9 is stacked on the surface of the intermediate member 7 on the opposite side from the chip 5 so as to close the through hole 7a. Each bonding member 3 includes a portion (upper end 3a) that is located on the opposite side of the lid 9 from the intermediate member 7, and is electrically connected to the corresponding terminal 15. The intermediate member 7 surrounds the terminals 15 and the functional part 5b as a result of including the through hole 7a located above the terminals 15 as well as above the functional part 5b. The lid 9 includes second through holes (through holes 9a) that extend through the lid 9 in the direction in which the upper surface 5a faces, at positions overlapping the terminals 15 out of the functional part 5b and the terminals 15 when the upper surface 5a is viewed in plan view. Each bonding member 3 includes a portion located on the opposite side of the through hole 9a from the intermediate member 7 (first portion 3aa), a portion located inside the through hole 9a (center portion 3b), and a portion located inside the through hole 7a and bonded to the terminal 15 (lower end 3c).

Thus, for example, the bonding members 3 themselves, which constitute bumps on the lid 9, are bonded to the terminals 15 of the chip 5, and the configuration is simple. In other words, there is no need to provide via conductors (columnar metal) between the terminals 15 and the bumps (bonding members 3). The terminals 15 and the bonding members 3 are bonded to each other inside the through hole 7a, which is for forming a space above the functional part 5b, and no dedicated through holes for bonding the terminals 15 and the bonding members 3 to each other are provided in the intermediate member 7. Thus, for example, the intermediate member 7 does not need to have partition walls partitioning dedicated through holes from the through hole 7a. As a result, there is an advantage in terms of size reduction, for example.

In this embodiment, the bonding members 3 may be composed of a metal having a liquid phase line temperature of less than 450° C.

In this case, for example, since the bonding members 3 are widely used for surface mounting, the electronic component 1 can be mounted on the mounting substrate 103 in the same way as has been previously used.

In this embodiment, each bonding member 3 may further include a portion (second portion 3ab of upper end 3a) located in the area surrounding the through hole 9a on the surface of the lid 9 on the opposite side from the intermediate member 7 (+D3 side).

In this case, for example, the volume of the portions of the bonding members 3 that are bonded to the mounting substrate 103 is more readily secured. As a result, the strength with which the electronic component 1 is bonded to the mounting substrate 103 can be improved while, for example, reducing the size of the electronic component 1 by reducing the diameter of the through holes 9a.

In this embodiment, the lid 9 may include conductors (conductor layers 27. More specifically, cylindrical portions 27b) that form the inner surfaces of the through holes 9a from the ends of the through holes 9a on the side near the intermediate member 7 (−D3 side) to the ends of the through holes 9a on the opposite side from the intermediate member 7 (+D3 side). The bonding members 3 may be in contact with the conductor layers 27.

In this case, for example, even if a bonding member 3 itself is broken, the separated portions of the bonding member 3 will be electrically connected to each other by the conductor layer 27. As a result, the reliability of the electrical connections between the bonding members 3 and the terminals 15 is improved. In addition, focusing on the process of manufacturing the electronic component 1, it is easier to dispose the bonding members 3 inside the through holes 9a because the bonding members 3 in a molten state typically have higher wettability with conductors (metals) than with insulators.

In this embodiment, the lid 9 may include the insulating substrate 25 stacked on the intermediate member 7 so as to close the through hole 7a, and conductors (upper flanges 27a) stacked on the areas surrounding the through holes 9a out of the surface of the insulating substrate 25 on the opposite side (+D3 side) from the intermediate member 7. The bonding members 3 may be in contact with the upper flanges 27a.

In this case, for example, since the bonding members 3 in a molten state typically have higher wettability with conductors (metals) than with insulators, it is easier to keep the bonding members 3 around the upper flanges 27a when the bonding members 3 are melted in order to mount the electronic component 1. As a result, for example, the likelihood of the bonding members 3 flowing to unintended positions and causing short circuits is reduced. In addition, focusing on the process of manufacturing the electronic component 1, the volume of the upper ends 3a is more easily secured because the bonding members 3 can be more easily kept around the upper flanges 27a.

The lid 9 may include the insulating substrate 25 stacked on the intermediate member 7 so as to close the through hole 7a, and conductors (lower flanges 27c) stacked on the areas surrounding the through holes 9a out of the surface of the insulating substrate 25 on the side near the intermediate member 7 (−D3 side). The bonding members 3 may be in contact with the lower flanges 27c.

In this case, for example, the distance between each through hole 9a and the corresponding terminal 15 (the length of the through hole 7a in the direction D3) can be shortened by the thickness of the lower flange 27c around the through hole 9a. As a result, for example, when mounting the electronic component 1 on the mounting substrate 103, the likelihood of any bonding member 3 becoming disconnected between the corresponding through hole 9a and terminal 15 can be reduced. Similarly to as with the upper flanges 27a, since the bonding members 3 can be easily kept around the lower flanges 27c, the likelihood of the bonding members 3 flowing to unintended positions and causing short circuits is reduced.

In this embodiment, the lid 9 may include the insulating substrate 25, which is stacked on the intermediate member 7 so as to close the through hole 7a, and the conductor layers 27. The insulating substrate 25 may include third through holes (through holes 25a) including the through holes 9a. The conductor layers 27 may each be stacked on the inner surface of the corresponding through hole 25a and form the inner surface of the corresponding through hole 9a. The insulating substrate 25 may include glass cloth (reinforcing material 31). The glass cloth may include portions located within the conductor layers 27.

In this case, for example, the bonding strength between the conductor layers 27 and the insulating substrate 25 is improved. Consequently, when a force acts on the bonding members 3 due to a difference in thermal expansion between the mounting substrate 103 and the electronic component 1, the likelihood of sealing of the through hole 7a becoming degraded due to the conductor layers 27 peeling off is reduced.

In this embodiment, the glass cloth (reinforcing material 31) of the insulating substrate 25 contains multiple fibers 32 that cross each other. The fibers 32 crossing each other include portions directly bonded to each other within the conductor layers 27.

In this case, for example, the strength of the inner peripheral surfaces of the through holes 25a of the insulating substrate 25 is improved due to the bonding between the mutually crossing fibers 32. Furthermore, since the bonding strength between the fibers 32, whose strength is improved as a result of being bonded together, and the conductor layers 27 is improved due to the fibers 32 entering the conductor layers 27, the above-mentioned effect (the effect in which the likelihood of sealing of the through hole 7a being degraded due to the conductor layers 27 peeling off when force is applied to the bonding members 3 due to a difference in thermal expansion between the mounting substrate 103 and the electronic component 1 is reduced) is also improved.

In this embodiment, the lid 9 may include the insulating substrate 25. The insulating substrate 25 may include the base material 29 composed of resin and the reinforcing material 31 composed of glass located inside the base material 29.

In this case, for example, the strength of the lid 9 can be improved compared with a case where the lid 9 is composed of only resin (this case may also be included in technologies of the present disclosure). For example, the Young's modulus of the lid 9 may be not less than 30 GPa and not more than 40 GPa. As a result, the bending deformation of the lid 9 is reduced. Since bending deformation of the lid 9 is reduced, the through hole 7a of the intermediate member 7, which is closed by the lid 9, can be made larger. This makes it easier to make the through hole 7a overlap the terminals 15 in addition to the functional part 5b. From another perspective, the width of the portion surrounding the through hole 7a of the intermediate member 7 can be decreased and this is advantageous in terms of size reduction.

In this embodiment, the coefficient of linear expansion of the intermediate member 7 may be smaller than the coefficient of linear expansion of the lid 9. The glass transition temperature of the intermediate member 7 may be larger than the glass transition temperature of the lid 9.

In this case, for example, the effect of deformation of the lid 9 caused by heat is less likely to be transmitted to the chip 5. As a result, the likelihood of unintended stress affecting the vibration of the functional part 5b from the lid 9, for example, is reduced. This stabilizes the electrical characteristics of the electronic component 1.

The electronic device 101 according to this embodiment includes the electronic components 1 as described above, the mounting substrate 103, and the sealing portion 105. The mounting substrate 103 has the mounting surface 103a facing the side of each electronic component 1 near the lid 9, and includes the pads 109 located on the mounting surface 103a and to which the bonding members 3 are bonded. The sealing portion 105 covers at least the side surfaces of the electronic components 1 and closely contacts the mounting surface 103a.

Since the electronic device 101 includes the electronic components 1 described above, the electronic device 101 can achieve the various effects described above exhibited by the electronic component 1. In addition, when a force acts on the electronic components 1 due to a difference in thermal expansion between the electronic components 1, the mounting substrate 103, and the sealing portion 105, the electronic components 1 deform so as to bend starting from the bonding members 3 since movement of the electronic component 1 is restricted due to the bonding members 3 being bonded to the mounting substrate 103. From another perspective, stress tends to concentrate at the bonding members 3. In the case where the bonding members 3 have the top flanges 27a at the upper ends 3a, the above stress is relieved since the volume of the upper ends 3a is readily secured.

The method of manufacturing the electronic component 1 also includes the bonding step (ST4) in which the chip 5, the intermediate member 7, and the lid 9 (in a wafer state or in an individual state) are bonded together, and after the bonding step, a bonding member disposing step (ST5) in which the bonding members 3 are supplied in a molten state to the through holes 9a in order to bond the bonding members 3 to the terminals 15.

Therefore, there is no need for a step of providing via conductors between the terminals 15 and the bonding members 3, and the manufacturing process is simplified.

(Variations)

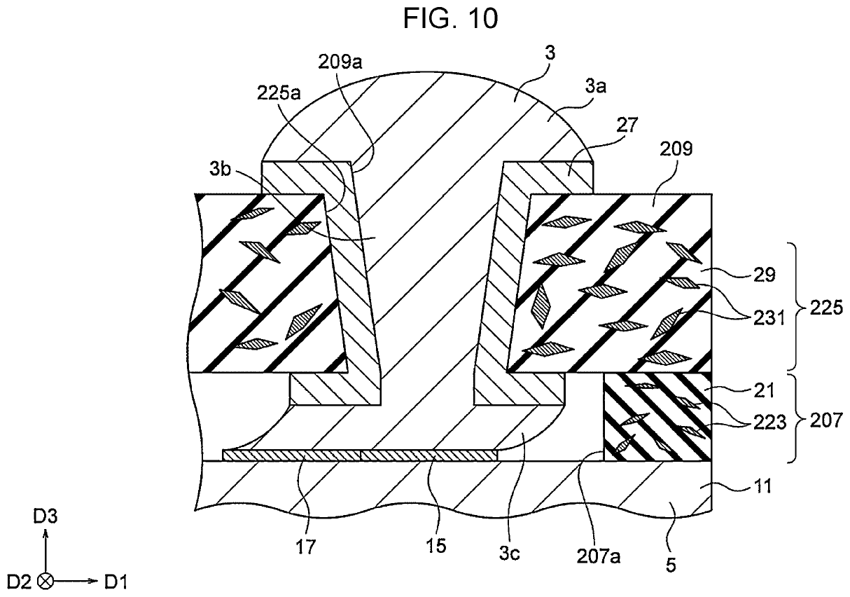

FIG. 10 is a cross-sectional view illustrating the configuration of an electronic component according to a variation and corresponds to FIG. 4. In the following description, matters not specifically mentioned may be assumed to be the same as or similar to those described in the embodiment.

As mentioned in the description of the embodiment, the shape and/or dimensions of a lateral cross section of each through hole 9a of the lid 9 may be constant regardless of the position in the direction in which the through hole 9a extends (example in FIG. 4) or may be different. In FIG. 10, as an example of the latter case, a through hole 209a of a lid 209 (or a through hole 225a of an insulating substrate 225 from another perspective) has a tapered shape that decreases in diameter with increasing proximity to the −D3 side. The angle of inclination of the inner surface of the through hole 209a and the difference between the diameter at the upper end and the diameter at the lower end of the through hole 209a may be set as appropriate. For example, the diameter at the upper end may be not less than 1.1 times and not more than 2 times the diameter at the lower end.

When the through hole 209a is tapered in this way, for example, it is easier to secure the volume of the upper end 3a of the bonding member 3. On the other hand, the volume of the lower end 3c of the bonding member 3 can be made smaller so as to reduce the likelihood of the lower end 3c protruding beyond the terminal 15. From another perspective, the terminal 15 can be made smaller in order to facilitate size reduction of the electronic component 1. Since the diameter of the upper end of the through hole 209a is large, it is easier to dispose the bonding member 3 inside the through hole 209a. On the other hand, the smaller diameter of the lower end of the through hole 209a makes it more likely for the bonding member 3 to remain within the through hole 209a, and this reduces the likelihood of more than the intended amount of the bonding member 3 flowing down into a through hole 207a of an intermediate member 207.

As described in the description of the embodiment, the reinforcing material 23 of the intermediate member 7 and the reinforcing material 31 of the insulating substrate 25 are not limited to being fabric-like (Sheet-like. From another perspective, fibers) and may consist of particles (the concept may include whiskers). In FIG. 10, an example is illustrated in which glass filler (particles) is used as a reinforcing material 223 of the intermediate member 207. An example is illustrated in which glass filler (particles) is used as the reinforcing material 231 of the insulating substrate 225. The glass is as described in the embodiment. The size and shape of the glass filler may be set as appropriate.

The embodiment and the variation may be combined as appropriate. For example, the tapered through hole 209a according to the variation may be combined with the insulating substrate 25 and/or intermediate member 7 including glass cloth according to the embodiment, or conversely, the straight columnar through hole 9a according to the embodiment may be combined with the insulating substrate 225 and/or intermediate member 207 containing glass filler according to the variation.

In the above embodiment and variation, the upper surface 5a of the chip 5 is an example of a first surface. The through holes 7a and 207a are examples of a first through hole. The through holes 9a and 209a are examples of a second through hole. The conductor layer 27 is an example of a conductor. The through holes 25a and 225a are examples of a third through hole. The reinforcing material 31 is an example of glass cloth. The element substrate 11 (at least the area of the upper surface where the functional part 5b is located) is an example of a piezoelectric body.

The technology according to the present disclosure is not limited to the above embodiments and may be implemented in various ways.

For example, the functional part is not limited to resonators or filters using acoustic waves. In other words, the chip is not limited to being an acoustic wave chip. For example, the functional part may generate vibrations in response to an acceleration applied to the electronic component. The chip may include a sensor that detects the acceleration and/or vibration by detecting a change in capacitance arising from the vibration of the above portion. The chip or functional part may be a micro electro mechanical system (MEMS).

When the functional part utilizes acoustic waves, the acoustic waves are not limited to SAWs. For example, the acoustic waves may be bulk acoustic waves (BAWs). A functional part utilizing BAWs may, for example, include an IDT like in the embodiment, or may include electrodes facing each other across a piezoelectric film above a cavity (piezoelectric thin film resonator).

### REFERENCE SIGNS

1 . . . electronic component,
3 . . . bonding member,
5 . . . chip,
5a . . . upper surface (first surface) (of chip),
5b . . . functional part,
7 . . . intermediate member,
7a . . . through hole (first through hole)
9 . . . lid,
9a . . . through hole (second through hole),
15 . . . terminal.

1. An electronic component comprising:
a chip having a first surface and including a functional part occupying a portion of the first surface and configured to vibrate, and a terminal occupying another portion of the first surface and electrically connected to the functional part;
an intermediate member stacked on the first surface, including, above the functional part, a first through hole extending through the intermediate member in a direction in which the first surface faces, and thereby surrounding the functional part when the first surface is viewed in plan view;
a lid stacked on a surface of the intermediate member on an opposite side from the chip and closing the first through hole; and
an electrically conductive bonding member electrically connected to the terminal and including a portion located on an opposite side of the lid from the intermediate member,
wherein the intermediate member surrounds the terminal as well as the functional part when the first surface is viewed in plan view as a result of the first through hole of the intermediate member being located above the terminal as well as above the functional part,
the lid includes a second through hole extending through the lid in a direction in which the first surface faces at a position overlapping the terminal out of the functional part and the terminal when the first surface is viewed in plan view, and
the bonding member includes a portion located on an opposite side of the second through hole from the intermediate member, a portion located inside the second through hole, and a portion located inside the first through hole and bonded to the terminal.

2. The electronic component according to claim 1,
wherein the bonding member is composed of a metal having a liquid phase line temperature of less than 450° C.

3. The electronic component according to claim 1,
wherein the bonding member further includes a portion located in an area surrounding the second through hole out of a surface of the lid on an opposite side from the intermediate member.

4. The electronic component according claim 1,
wherein the lid includes a conductor forming an inner surface of the second through hole from an end of the second through hole on a side near the intermediate member to an end of the second through hole on an opposite side from the intermediate member, and
the bonding member is in contact with the conductor.

5. The electronic component according to claim 1,
wherein the lid includes an insulating substrate stacked on the intermediate member and closing the first through hole, and
a conductor stacked on an area surrounding the second through hole out of a surface of the insulating substrate on an opposite side from the intermediate member, and
the bonding member is in contact with the conductor.

6. The electronic component according to claim 1,
wherein the lid includes an insulating substrate stacked on the intermediate member and closing the first through hole, and
a conductor stacked on an area surrounding the second through hole out of a surface of the insulating substrate on a side near the intermediate member, and
the bonding member is in contact with the conductor.

7. The electronic component according to claim 1,
wherein the lid includes an insulating substrate stacked on the intermediate member and closing the first through hole, the insulating substrate including a third through hole including the second through hole, and
a conductor layer stacked on an inner surface of the third through hole and forming an inner surface of the second through hole,
the insulating substrate includes glass cloth, and
the glass cloth includes a portion located inside the conductor layer.

8. The electronic component according to claim 7,
wherein the glass cloth contains multiple fibers that cross each other, and
the fibers that cross each other include portions that are directly bonded to each other inside the conductor layer.

9. The electronic component according to claim 1,
wherein the lid includes an insulating substrate, and
the insulating substrate consists of a base material composed of resin and
a reinforcing material composed of glass located inside the base material.

10. The electronic component according to claim 1,
wherein a coefficient of linear expansion of the intermediate member is smaller than a coefficient of linear expansion of the lid, and
a glass transition temperature of the intermediate member is larger than a glass transition temperature of the lid.

11. The electronic component of claim 1,
wherein the functional part includes a piezoelectric body and
an excitation electrode located on the piezoelectric body and electrically connected to the terminal.

12. An electronic device comprising:
the electronic component according to claim 1;
a mounting substrate having a mounting surface facing a side of the electronic component where the lid is located, and including a pad that occupies a portion of the mounting surface and to which the bonding member is bonded; and
a sealing portion covering at least a portion of an outer peripheral surface of the chip on a side near the mounting surface and closely contacting the mounting surface.

13. A method of manufacturing the electronic component according to claim 1, the method comprising:
a bonding step of bonding the chip, the intermediate member, and the lid to each other; and
a bonding member disposing step in which, after the bonding step, the bonding member, in a molten state, is supplied into the second through hole and bonds to the terminal.
